(19) United States
(12) Patent Application Publication
(10) Pub. No.: US 2026/0052747 A1
(43) Pub. Date: Feb. 19, 2026

(54) SEMICONDUCTOR DEVICES HAVING REDUCED CONTACT RESISTIVITY

(71) Applicant: Applied Materials, Inc., Santa Clara, CA (US)

(72) Inventors: Sefa DAG, Fremont, CA (US); Ning YANG, Sunnyvale, CA (US); El Mehdi BAZIZI, San Jose, CA (US); Zhebo CHEN, Santa Clara, CA (US); Alexander JANSEN, Danville, CA (US); Gang SHEN, San Jose, CA (US)

(73) Assignee: Applied Materials, Inc., Santa Clara, CA (US)

(21) Appl. No.: 18/807,144

(22) Filed: Aug. 16, 2024

(51) Int. Cl. H01L 21/285; H01L 29/45

(52) U.S. Cl. CPC H01L 21/28518; H10D 64/62

(57) ABSTRACT

The present technology includes semiconductor devices and methods with improved contact resistivity. Semiconductor devices include a substrate base, a contact including a silicide overlying at least a portion of the substrate in the one or more features, which has a contact length of less than 40 Angstroms. The methods for generating a reduced contact length silicide layer includes depositing a first metal, and performing at least one thermal anneal to generate a silicide having a reduced contact length.

### TECHNICAL FIELD

The present technology relates to methods for semiconductor processing and devices formed therefrom. More specifically, the present technology relates to methods for reducing the contact resistivity of semiconductor devices and devices incorporating such contacts.

### BACKGROUND

Integrated circuits have advanced into complex devices that can include millions of transistors, capacitors, and resistors on a single chip. In the course of integrated circuit evolution, functional density (i.e., the number of interconnected devices per chip area) has generally increased while geometry size has decreased. Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate field-effect transistors (FETs) in which current flows through a semiconducting channel between a source and a drain, in response to a voltage applied to a control gate.

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. As devices shrink and more complex patterning schemes are utilized in the industry, deposition of thin films becomes a challenge. In addition, as material thicknesses continue to reduce, as-deposited characteristics of the films may have a greater impact on device performance.

Thus, there is a need for high-quality devices and structures having improved resistance, and methods of making such devices. These and other needs are addressed by the present technology.

### BRIEF SUMMARY

The present technology is generally directed to semiconductor devices and methods with improved contact resistivity. Semiconductor devices include a substrate having one or more features and a contact including a silicide overlying at least a portion of the substrate in one or more features. The contact of the silicide overlying at least a portion of the substrate can include a contact length of less than 40 Angstroms.

In embodiments, contact exhibits a Schottky Barrier Height that is at least about 5% less than a Schottky Barrier Height in a contact that comprises a contact length of greater than 40 Angstroms. In embodiments, the contact exhibits a Schottky Barrier Height of less than 0.5 eV. In more embodiments, the contact length is less than or about 30 Angstroms. In further embodiments, the contact height is less than or about 20 Angstroms.

In further embodiments, the silicide includes at least a first metal. In embodiments, the first metal is titanium, zirconium, nickel, molybdenum, or a combination thereof. In embodiments, the silicide in a mono-silicide, a di-silicide, or a combination thereof. In yet more embodiments, the interface between the substrate and the contact includes greater than or about 40% of metal atoms per area. In embodiments, the contact is disposed in a n-MOS region. Additionally, or alternatively, in embodiments, the silicon oxide layer is disposed in a p-MOS region.

Embodiments of the present technology include semiconductor devices with improved contact resistivity. Semiconductor devices include a silicon-containing substrate, an oxide disposed on the substrate defining one or more features, and a contact comprising a silicide overlying at least a portion of the silicon-containing substrate in the one or more features. The contact including the silicide overlying at least a portion of the silicon-containing substrate includes a contact length of less than 40 Angstroms.

In embodiments, the silicide includes at least a first metal. The at least first metal includes molybdenum, titanium, zirconium, nickel, or a combination thereof. In yet further embodiments, the contact exhibits a Schottky Barrier Height of less than 0.5 eV.

The present technology is also generally directed to methods of forming semiconductor devices. Methods include depositing at least a first metal layer including a first metal over a silicon containing substrate. Methods include annealing the semiconductor device, forming a metal silicide contact between the silicon containing substrate and the at least the first metal layer. The contact includes a contact length of less than 40 Angstroms.

In embodiments, the metal silicide contact is a mono-silicide or a di-silicide. Furthermore, in embodiments, depositing the first metal layer includes exposing the silicon oxide layer to a first metal precursor and a first metal reactant. In further embodiments, the contact exhibits a Schottky Barrier Height of less than 0.5 eV. In yet more embodiments, the at least a first metal layer is deposited in a p-MOS region or a n-MOS region of a semiconductor device. In further embodiments, the contact length is less than or about 20 Angstroms. In yet further embodiments, the method further includes a second annealing operation subsequent to the annealing.

Such technology may provide numerous benefits over conventional techniques. For example, embodiments of the present technology provide improved contact strength and reduced contact resistivity, even at small contact sizes. In addition, the present technology allows for control over the degree and strength of the contacts. The present technology may therefore provide for improved contacts without requiring annealing methods that may be damaging to substrates. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing chamber according to some embodiments of the present technology.

FIG. 2 shows selected operations in a formation method according to some embodiments of the present technology.

FIGS. 3A-3C show cross-sectional views of exemplary semiconductor structures according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Microelectronic devices are fabricated on semiconductor substrates as integrated circuits in which various conductive layers are interconnected with one another to permit electronic signals to propagate within the device. Such devices may include transistors, such as include complementary metal-oxide-semiconductors (CMOS), field effect transistors (FET), MOSFETs including both planar and three-dimensional structures, including finFETs, gate-all-around FETs, and nanosheet FETs, among other types of transistors. Drive current, and therefore speed, of a transistor is proportional to a gate width of the transistor. Faster transistors generally require larger gate width. There is a trade-off between transistor size and speed, and “fin” field-effect transistors (finFETs) and gate-all-around FETs have been developed as examples to address the conflicting goals of a transistor having maximum drive current and minimum size.

An exemplary finFET or MOSFET includes a gate electrode on a gate dielectric layer on a surface of a semiconductor substrate. Source and drain regions are provided along opposite sides of the gate electrode. The source and drain regions are generally heavily doped regions of the semiconductor substrate (p-doped or n-doped). Usually a capped silicide layer, for example, molybdenum silicide, is used to couple contacts, to the source and drain regions. However, such caps, as well as shrinking contacts has led to undesirably high contact resistivity for continued improvement in electrical properties, particularly in smaller technologies. Namely, due at least in part to limited contact surface area between source end drain regions and corresponding metal contacts, contact resistance is problematically high for continuously shrinkage and/or increasing drive in semiconductor devices.

In addition, during middle-of-line (MOL) processes, a minimum via resistance for the MOL structures is targeted. However, MOL contact dimensions are also impacted by technology scaling. Proper reduction of the contact sizes can therefore create significant increases in contact resistance. For instance, it is estimated that the epi-substrate to silicide contact can contribute greater than 80% of the total resistance of the respective device. Attempts have been made to alter the silicidation process to improve deposition, reduce oxidation, and utilize different materials. In addition, conventional processes have suggested utilizing high temperature thermal annealing processes in an attempt to improve contact adhesion and/or interface crystallinity. However, such methods proved insufficient to improve contact resistivity to the levels required of the art, and also reduces the materials that could be utilized elsewhere on the device due to the high thermal budget caused by the high temperatures (e.g., films, liners, etc. that cannot withstanding high anneal temperatures).

The present technology overcomes these and other challenges by providing a strong and robust contact, thus facilitating a decrease in barrier height and lower contact resistivity. Namely, the present technology has surprisingly found that by utilizing a reduced contact length, the strength and resistivity of the contact is greatly improved. In embodiments of the present technology, a first metal layer is applied over a silicon containing layer, and a metal silicide layer is generated having a contact length of less than 40 Angstroms. This was surprising, as it was previously believed that greater contact lengths (e.g. greater than 40 Angstroms, or even greater than 50 Angstroms) were necessary to achieve a robust contact. However, by utilizing the methods and devices discussed herein, the present technology has surprisingly found that adhesion between layers of the contact are improved while exhibiting a reduced contact length (e.g., less than 40 Angstroms contact length). Furthermore, the present technology has found that such an approach improved contact resistivity in both p-MOS and n-MOS regions.

Although the remaining disclosure will routinely identify specific metal-oxide-semiconductor field-effect transistors (MOSFET), complementary metal-oxide semiconductors (CMOS), and components thereof, it will be readily understood that the device and methods are equally applicable to other field-effect transistors, orientations thereof, as processes for forming such devices. Accordingly, the technology should not be considered to be so limited as for use with these specific devices or methods alone. The disclosure will discuss one possible semiconductor device that may include one or more components, utilizing one or more self-aligned single diffusion breaks according to embodiments of the present technology before additional variations and adjustments to this apparatus according to embodiments of the present technology are described.

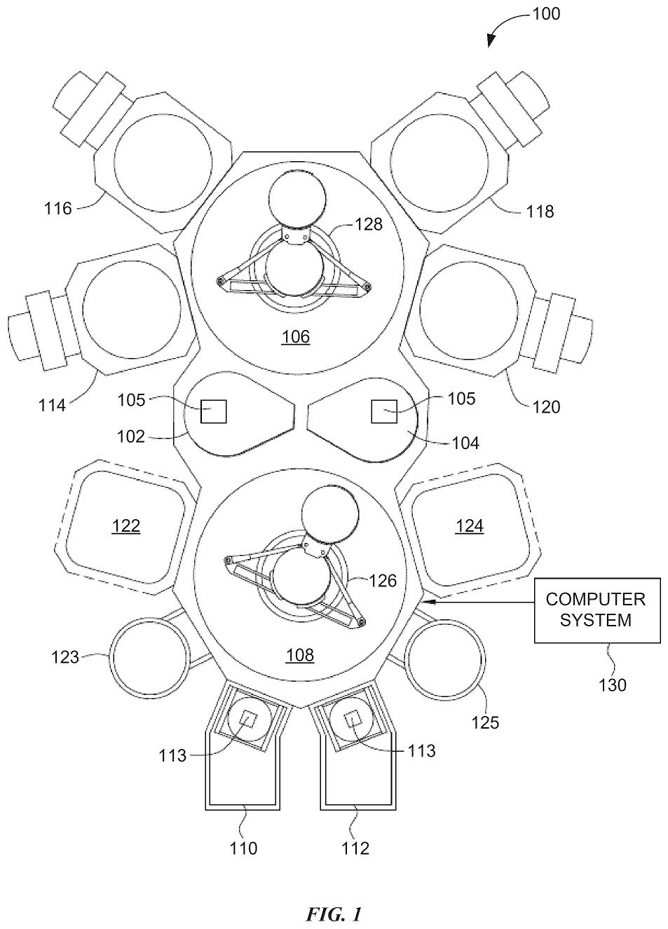

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

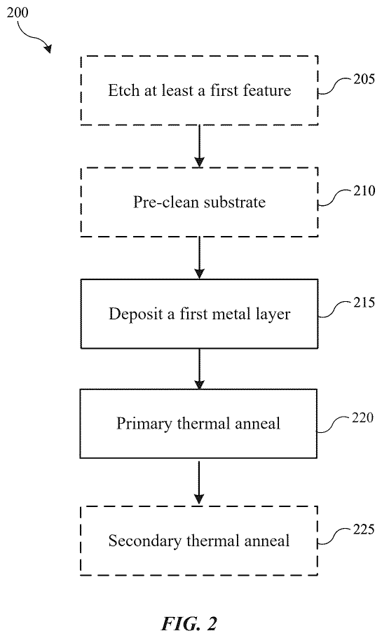

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

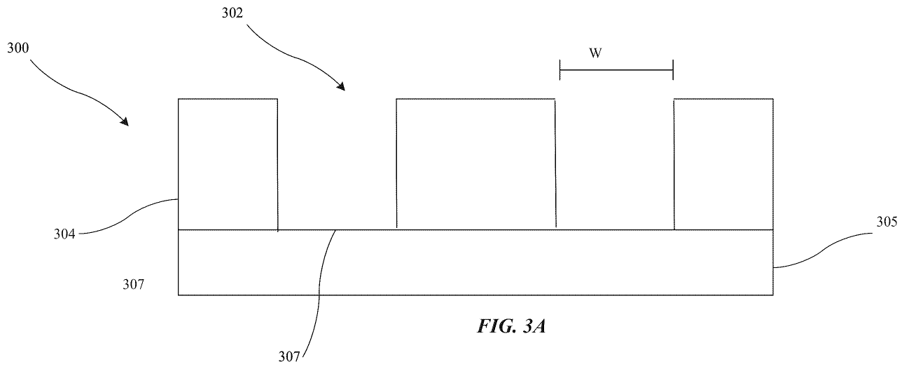

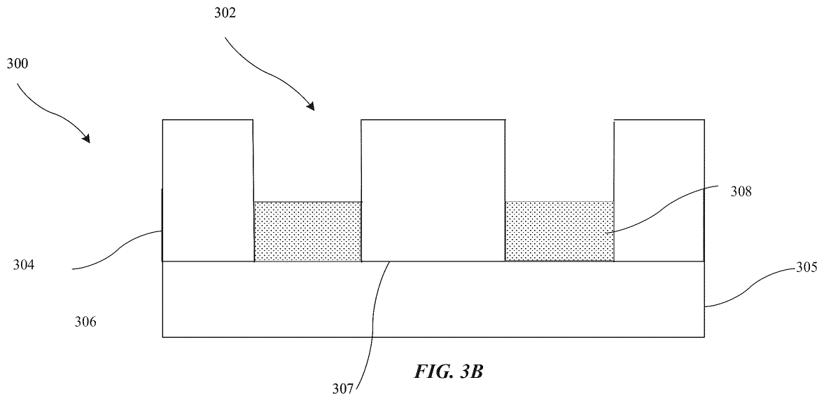

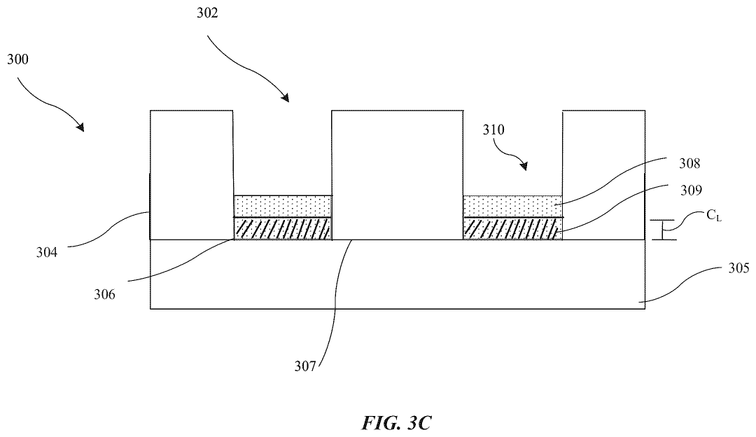

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing system 100, such as processing chamber 114, 116, 118, 120, 122, and/or 124 described above, or other chambers that may include components as described above. The substrate may be deposited on a substrate support, which may be a pedestal such as substrate platform 104, and which may reside in a processing region of the chamber, such as processing region 120 described above. Method 200 describes operations shown schematically in FIGS. 3A-3C, the illustrations of which will be described in conjunction with the operations of method 200. It is to be understood that FIGS. 3A-3C illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular polishing operation, such as one or more semiconductor processing operations to develop one or more layers of material on a substrate, clamping a substrate to a carrier head of a polishing system, or depositing one or more metal layers in one or more features 302. It is to be understood that method 200 may be performed on any number of semiconductor structures or substrates 305, as illustrated in FIG. 3A, including exemplary structure 300 on which silicon oxide 304 may be formed over substrate 305. For instance, in embodiments, an operation 205 may include transferring a substrate 305 to a deposition chamber, such as process chamber 114, to etch one or more features 302 in silicon oxide 304.

Structure 300 may illustrate a partial view of a substrate, which in embodiments may be used in n-channel and p-channel MOSFETs, FinFETs, gate-all-around FETs, complementary metal-oxide semiconductors, and nanosheet FETs, among other types of semiconductor transistor structures. The layers of material may be produced by any number of methods, including chemical vapor deposition (CVD), physical vapor deposition (PVD), atomic layer deposition (ALD), thermally enhanced chemical vapor deposition (TECVD), plasma-enhanced chemical vapor deposition (PECVD), plasma enhanced atomic layer deposition (PEALD), or any other formation technique. In embodiments, any one or more deposition methods or operations may be performed in a processing chamber, such as processing chamber 118 and/or 120 described previously. Substrate layers can include silicon oxide and silicon nitride, silicon oxide and silicon, silicon nitride and silicon, silicon and doped silicon, or any number of other materials.

However, in embodiments, the substrate 305 may be a bulk semiconductor substrate. As used herein, the term “bulk semiconductor substrate” refers to a substrate in which the entirety of the substrate is comprised of a semiconductor material. The bulk semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, silicon germanium, epi-substrate, gallium arsenide, or other suitable semiconducting materials. In embodiments, the semiconductor material is silicon (Si). In one or more embodiments, the semiconductor substrate 305 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 305 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. As discussed above, in embodiments, the present technology may provide improved mobility in both p and n-type semiconductors (also referred to p-MOS and n-MOS regions herein).

Although the following description will regularly discuss silicon oxide deposited on the substrate 305 as a dielectric material, it is to be understood that any number of dielectric materials may be used in embodiments of the present technology, and the present technology should not be limited to any particular dielectric material in which features may be formed. As illustrated in FIG. 3A, the silicon oxide 304 may be processed to form one or more recesses or features 302, such as trenches, apertures or vias, or any other structure useful in semiconductor processing, having a width (W). Substrate 305 may be any number of materials, such as a base wafer or substrate 305 made of silicon or silicon-containing materials, or other substrate materials as discussed above. In embodiments, methods can include optional steps of etching 205 one or more features 302 in an etching chamber, such as processing chamber 114. Although two features 302 are shown in the figure, it is to be understood that exemplary structures may have any number of features defined along the structure according to embodiments of the present technology. Thus, in embodiments, only one feature may be formed, or more than 2, such as greater than 3, such as greater than 4, such as greater than 5, such as greater than 6, such as greater than 7, such as greater than 8, such as greater than 9, such as greater than 10 features may be formed, or any ranges or values therebetween.

Nonetheless, in embodiments, an optional etch operation 205 may be a first operation in processing system 100 depending upon prior processing steps. If so, a substrate 305 may be loaded into load lock 110,112 and transferred to an etch chamber (such as process chamber 114) via robots 126, 128. Thus, the etch process may be considered to be an in-situ etch process within process system 100. However, in embodiments, the transfer may be from a first process chamber (such as process chamber 114) to a second process chamber 116, instead of loading through load locks 110, 112 if a prior operation is performed according to method embodiments. Namely, as will be discussed in greater detail below, in embodiments, prevention and removal of oxides may be necessary for proper annealing of the one or more metal layers utilized for forming the silicide layer having a reduced contact length of the present technology. Thus, in aspects, processing system 100 may provide an end-to-end platform such that each operation, including transfer therebetween, may be conducted under vacuum.

However, in embodiments, it may be desirable to conduct an optional pre-clean operation 210 to remove any existing oxides, or if a full vacuum process is not feasible, either before or after etch operation 205. In embodiments, the cleaning operation (also referred to as a pre-clean operation) is any cleaning process suitable for removing an oxide layer from substrate 305. For instance, in embodiments, a plasma assisted etch process, a reactive etch or clean process, the like, or a combination thereof may be conducted in order to remove any byproducts formed on the substrate, such as surface oxidation. In embodiments, a preclean operation 210 may be conducted via a Siconi™ etch process, or any reactive etch or clean process known in the art. For instance, such a pre-clean may be selected to remove silicon oxides formed on an upper surface 307 of a substrate 305 within feature 302, as an example only. Nonetheless, in embodiments, a substrate 305 may be transferred from etch chamber 114 to a preclean chamber (such as process chamber 116) via robots 126, 128. Thus, the pre-clean process may be considered to be an in-situ clean process within process system 100.

Moreover, as discussed above, in embodiments, after a preclean process, the substrate 305 is transferred under vacuum, to a deposition chamber, such as a process chamber 118. Namely, oxide formation on the silicon-containing substrate 305 can prevent diffusion of the one or more metals into the silicon containing substrate 305. Thus, in embodiments, transfer to a deposition chamber 118 under vacuum may be necessary in order to prevent formation of further oxides after the pre-clean operation 210.

Nonetheless, in embodiments, a first metal layer 308 containing a first metal is deposited over the substrate 305 in feature 302 as shown in FIG. 3B at operation 215. In embodiments, deposition can be according to any suitable method in the art, and may be conducted in a processing chamber configured as a chemical vapor deposition chamber, a physical vapor deposition chamber, an atomic layer deposition chamber, a thermally enhanced chemical vapor deposition chamber, a plasma-enhanced chemical vapor deposition chamber, an electroless deposition chamber, or a plasma enhanced atomic layer deposition chamber.

In embodiments, the first metal may be or include tungsten, molybdenum, titanium, zirconium, nickel, hafnium, cobalt, tin, tantalum, platinum, iron, niobium, palladium, a metal-containing species thereof, alloys thereof, or combinations thereof. However, it should be understood that, in embodiments, the first metal may be a low resistivity, conductive metal as known in the art. Nonetheless, in embodiments, the first metal is molybdenum, titanium, zirconium, nickel, metal-containing species thereof, alloys thereof, or combinations thereof. In embodiments, the first metal is molybdenum, metal-containing species thereof, or alloys thereof.

Deposition of the first metal 215 may include a masking operation as known in the art to mask areas of structure 300 that it is undesirable to deposit a first metal layer 308 (e.g., all areas other than features 302). Nonetheless, deposition of the first metal layer 308 may include exposing the feature(s) 302, which may include the first metal layer and the dielectric material, which may be silicon oxide, to a metal precursor and a first metal reactant, which may be a precursor of any one or more of the first metals discussed above, forming first metal layer 308 in one or more features 302. As used in this specification and the appended claims, the terms “reactive compound”, “reactive gas”, “reactive species”, “precursor”, “process gas” and the like are used interchangeably to mean a substance with a species capable of reacting with the substrate 305 (or substrate surface 307) or material on the substrate 305 (or substrate surface) in a surface reaction (e.g., chemisorption, oxidation, reduction). In embodiments, the precursor may be a metal vapor or plasma (e.g., when utilizing a PVD process), or may be a precursor and a reactant, as well as other precursor forms as known in the art.

Regardless of the method selected, the first metal layer 308 is deposited at a lower thickness than previously believed possible for semiconductor structures. As discussed above, previously, it was believed that a large depth or thickness of metal (e.g. greater than 40 or even 50 Angstroms) was necessary for a robust silicide contact, as it was believed that the work function of the material improved the contact properties, and greater amounts of material increased the available work function. However, surprisingly, the present technology has found that the opposite is true, and that lower contact thicknesses allow for improved barrier height, and interface energies. Thus, in embodiments, the first metal layer 308 may be deposited at a thickness suitable (and therefore a suitable deposition time) to form a final silicide contact length of less than 50 Angstroms, such as less than 40 Angstroms, as will be discussed below, and may therefore be deposited a thickness of less than or about 50 Angstroms, less than or about 48 Angstroms, less than or about 46 Angstroms, less than or about 44 Angstroms, less than or about 42 Angstroms, less than or about 40 Angstroms, less than or about 38 Angstroms, less than or about 36 Angstroms, less than or about 34 Angstroms, less than or about 32 Angstroms, less than or about 30 Angstroms, less than or about 28 Angstroms, less than or about 26 Angstroms, less than or about 24 Angstroms, less than or about 22 Angstroms, less than or about 20 Angstroms, less than or about 18 Angstroms, less than or about 16 Angstroms, less than or about 14 Angstroms, less than or about 12 Angstroms, less than or about 10 Angstroms, or any ranges or values therebetween. In embodiments, any one or more of the above ranges may refer to a thickness of each layer, or may refer to a total overall thickness of the one or more metals deposited over the substrate.

In embodiments, the substrate 305 is transferred under vacuum, to a deposition chamber, such as a process chamber 120. Namely, oxide formation on the first metal layer 308 can prevent diffusion of the metals into the silicon containing substrate 305. Thus, in embodiments, transfer to a deposition chamber, which may be the same deposition chamber 118 or a second deposition chamber 120 under vacuum may be necessary in order to prevent formation of further oxides. Additionally or alternatively, an optional further cleaning process according to any one or more of the above described cleaning operations 210 may be conducted.

Regardless of the method utilized to form the first metal layer 308, the substrate 305 may be exposed to a primary thermal anneal process at operation 220 in order to form the silicide contact 310 driving metal ions 309 towards interface 306. The contact may be a silicide (e.g. mono-silicide) and/or a di-silicide contact, as the present technology has found that the contact properties are improved when both silicides and di-silicides are utilized. As illustrated in FIG. 3C, during the diffusion process, metal atoms of the first metal layer 308 may diffuse towards or accumulate at the interface region 306 of the substrate 305. The present technology has surprisingly found that by utilizing a thickness or depth of the one or more metal materials as discussed above, an increase in metal atoms at the substrate/silicide interface 306 actually increases. Whereas, in prior attempts, it was believed that larger depths or thicknesses of the one or more metals was necessary to increase the metal content at the interface 306. Furthermore, such an increase may contribute to improved resistivity, barrier height, and interfacial energy of the contact. In addition, without wishing to be bound by theory, the present technology has found that increasing the anneal time, or conducting a secondary anneal operation may further improve the metal content at the contact interface 306, as will be discussed in greater detail below.

In embodiments, the primary anneal may be conducted at a temperature of greater than or about 300° C., greater than or about 310° C., greater than or about 320° C., greater than or about 330° C., greater than or about 340° C., greater than or about 350° C., greater than or about 360° C., greater than or about 370° C., greater than or about 380° C., greater than or about 390° C., greater than or about 400° C., greater than or about 410° C., greater than or about 420° C., greater than or about 430° C., greater than or about 440° C., greater than or about 450° C., greater than or about 460° C., greater than or about 470° C., greater than or about 480° C., greater than or about 490° C., greater than or about 500° C., greater than or about 510° C., greater than or about 520° C., greater than or about 530° C., greater than or about 540° C., greater than or about 550° C., greater than or about 560° C., greater than or about 570° C., greater than or about 580° C., greater than or about 590° C., greater than or about 600° C., greater than or about 610° C., greater than or about 620° C., greater than or about 630° C., greater than or about 640° C., greater than or about 650° C., greater than or about 660° C., greater than or about 670° C., greater than or about 680° C., greater than or about 690° C., greater than or about 700° C., greater than or about 710° C., greater than or about 720° C., greater than or about 730° C., greater than or about 740° C., greater than or about 750° C., greater than or about 760° C., greater than or about 770° C., greater than or about 780° C., greater than or about 790° C., greater than or about 800° C., greater than or about 810° C., greater than or about 820° C., greater than or about 830° C., greater than or about 840° C., greater than or about 850° C., greater than or about 860° C., greater than or about 870° C., greater than or about 880° C., greater than or about 890° C., up to about 900° C., or any ranges or values therebetween. Advantageously, in embodiments, the annealing temperature may be less than or about 800° C., less than or about 750° C., less than or about 700° C., less than or about 675° C., less than or about 650° C., or any ranges or values therebetween, alone or in combination with the above. Namely, the metal layer according to the present technology may exhibit excellent electrical properties even without high temperature annealing, which may allow for greater material use in the structure due to the reduced thermal budget.

In embodiments, the primary annealing may occur from greater than or about 5 seconds up to about 600 seconds, such as greater than or about 10 seconds, greater than or about 20 seconds, greater than or about 30 seconds, greater than or about 40 seconds, greater than or about 50 seconds, greater than or about 60 seconds, greater than or about 70 seconds, greater than or about 80 seconds, greater than or about 90 seconds, greater than or about 100 seconds, greater than or about 110 seconds, greater than or about 120 seconds, greater than or about 130 seconds, greater than or about 140 seconds, greater than or about 150 seconds, greater than or about 160 seconds, greater than or about 170 seconds, greater than or about 180 seconds, greater than or about 190 seconds, greater than or about 200 seconds, greater than or about 210 seconds, greater than or about 220 seconds, greater than or about 230 seconds, greater than or about 240 seconds, greater than or about 250 seconds, greater than or about 260 seconds, greater than or about 270 seconds, greater than or about 280 seconds, greater than or about 290 seconds, greater than or about 300 seconds, greater than or about 310 seconds, greater than or about 320 seconds, greater than or about 330 seconds, greater than or about 340 seconds, greater than or about 350 seconds, greater than or about 360 seconds, greater than or about 370 seconds, greater than or about 380 seconds, greater than or about 390 seconds, greater than or about 400 seconds, greater than or about 410 seconds, greater than or about 420 seconds, greater than or about 430 seconds, greater than or about 440 seconds, greater than or about 450 seconds, greater than or about 460 seconds, greater than or about 470 seconds, greater than or about 480 seconds, greater than or about 490 seconds, greater than or about 500 seconds, greater than or about 510 seconds, greater than or about 520 seconds, greater than or about 530 seconds, greater than or about 540 seconds, greater than or about 550 seconds, greater than or about 560 seconds, greater than or about 570 seconds, greater than or about 580 seconds, greater than or about 590 seconds, or any ranges or values therebetween.

In embodiments, the annealing may be conducted in an environment that reduces the risk of oxidation to the substrate. Namely, as discussed above, oxidation or surface damage may prevent formation of the silicide contact. Thus, in embodiments may be conducted in the presence of an inert gas atmosphere, at a pressure of less than or about 1 Torr.

Nonetheless, a contact according to the present technology may exhibit a percentage of metal atoms at the silicide/substrate interface 306 of greater than or about 20%, greater than or about 22.5%, greater than or about 25%, greater than or about 27.5%, greater than or about 30%, greater than or about 32.5%, greater than or about 35%, greater than or about 37.5%, greater than or about 40%, greater than or about 42.5%, greater than or about 45%, greater than or about 47.5%, greater than or about 50%, greater than or about 52.5%, greater than or about 55%, greater than or about 57.5%, greater than or about 60%, or any ranges or values therebetween, based upon the amount, or number, of atoms at the interface based on the total number of atoms in the interface area at the silicide/substrate interface.

Furthermore, as discussed above, the contact length (CL) of the silicide may be less than 50 Angstroms. For example, the CL of the silicide at the interface may be than or about 50 Angstroms, less than or about 48 Angstroms, less than or about 46 Angstroms, less than or about 44 Angstroms, less than or about 42 Angstroms, less than or about 40 Angstroms, less than or about 38 Angstroms, less than or about 36 Angstroms, less than or about 34 Angstroms, less than or about 32 Angstroms, less than or about 30 Angstroms, less than or about 28 Angstroms, less than or about 26 Angstroms, less than or about 24 Angstroms, less than or about 22 Angstroms, less than or about 20 Angstroms, less than or about 18 Angstroms, less than or about 16 Angstroms, less than or about 14 Angstroms, less than or about 12 Angstroms, less than or about 10 Angstroms, or any ranges or values therebetween.

In additional embodiments, a secondary thermal anneal, operation 225, may be performed on the first metal layer 308 in feature 302 as shown in FIG. 3C further improving the adhesion between the silicide and the first metal and further enhancing the metal content of the silicide/substrate interface. During the secondary annealing, additional first metal atoms of the first metal layer 308 may diffuse towards or accumulate at the interface region of the substrate 305 and the upper surface 307 of the substrate 305. In embodiments, the concentration of metal at the interface 306 be illustrated by a percentage of metal atoms at the silicide/substrate interface 306 of greater than or about 20%, greater than or about 22.5%, greater than or about 25%, greater than or about 27.5%, greater than or about 30%, greater than or about 32.5%, greater than or about 35%, greater than or about 37.5%, greater than or about 40%, greater than or about 42.5%, greater than or about 45%, greater than or about 47.5%, greater than or about 50%, greater than or about 52.5%, greater than or about 55%, greater than or about 57.5%, greater than or about 60%, or any ranges or values therebetween, based upon amount, or number, of atoms at the silicide/substrate interface based on the total number of atoms in the area of the silicide/substrate interface.

In embodiments, the secondary thermal anneal, at operation 225 may be the same as the primary thermal anneal, at operation 220. For example, the length of time of the thermal anneal, and the temperature of the thermal anneal may be the same as the primary thermal anneal. In some embodiments, the secondary thermal anneal may be for a different duration of time and at a different temperature as compared to the primary thermal anneal. However, as discussed above, in embodiments, an anneal time of the primary anneal may be increased, instead of utilizing two separate annealing operations.

Namely, the present technology has found that by reducing the contact length of the silicide, results in a semiconductor device or a contact thereof which may exhibit a Schottky Barrier Height that is at least about 5% less than a Schottky Barrier Height or contact in a semiconductor device formed identically except that the device contains one or more silicide contacts having a contact length of greater than 40 angstroms, or even greater than 50 Angstroms, such greater than or about 6% less, such as greater than or about 7% less, such as greater than or about 8% less, such as greater than or about 9% less, such as greater than or about 10% less, such as greater than or about 12.5% less, such as greater than or about 15% less, such as greater than or about 17.5% less, such as greater than or about 20% less, such as greater than or about 22.5% less, such as greater than or about 25% less, such as greater than or about 30% less, greater than or about 32.5% less, greater than or about 35% less, greater than or about 37.5% less, greater than or about 40% less, greater than or about 42.5% less, or any ranges or values therebetween.

Stated different, in embodiments, a resulting semiconductor device, or a contact thereof, formed utilizing a silicide contact according to the present technology may have a Schottky Barrier Height of less than or about 1.0 eV, such as less than or about 0.9 eV, such as less than or about 0.85 eV, such as less than or about 0.8 eV, such as less than or about 0.75 eV, such as less than or about 0.7 eV, such as less than or about 0.65 eV, such as less than or about 0.6 eV, such as less than or about 0.55 eV, such as less than or about 0.5 eV, such as less than or about 0.45 eV, such as less than or about 0.4 eV, such as less than or about 0.35 eV, such as less than or about 0.3 eV, such as less than or about 0.25 eV, such as less than or about 0.2 eV, or any ranges or values therebetween.

In embodiments, the interfacial bond between the silicide layer and the substrate may be greatly improved. For instance, in embodiments, the silicide contact exhibits an adhesive energy (cohesive force) to the substrate that is at least about 3% greater than the adhesive energy between a silicide layer having a contact length of greater than 40 Angstroms, such as greater than or about 4%, such as greater than or about 5%, such as greater than or about 6%, such as greater than or about 7%, such as greater than or about 8%, such as greater than or about 9%, such as greater than or about 10%, such as greater than or about 11%, or any ranges or values therebetween. Stated differently such an interfacial bond may also be expressed as the cohesive/adhesive energy between the silicide and the substrate.

Stated differently, in embodiments, a device formed according to the present technology, or a contact thereof, may exhibit an interfacial energy of greater than or about −16 eV, greater than or about −16.5 eV, greater than or about −17 eV, greater than or about −17.5 eV, greater than or about −18 eV, greater, than or about −18.5 eV, greater than or about −19 eV, greater than or about −19.5 eV, greater than or about −20 eV, greater than or about −20.5 eV, greater than about −21 eV, greater than about −21.5 eV, greater than or about −22 eV, greater than or about −22.5 eV, greater than or about −23 eV, greater than or about −23.5 eV, greater than or about −24 eV, or any ranges or values therebetween.

After formation of the silicide contact 310, structures 300 may undergo deposition or formation of further layers or features. Additionally or alternatively, the structure 300 may be transferred to a polishing operation, an interconnect deposition operation, or any other operation as known in the art.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a metal” includes a plurality of such metals, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor device, comprising:
a substrate having one or more features; and
a contact comprising a silicide overlying at least a portion of the substrate in the one or more features;
wherein the contact comprises a contact length of less than 40 Angstroms.

2. The semiconductor device of claim 1, wherein the contact exhibits a Schottky Barrier Height that is at least about 5% less than a Schottky Barrier Height in a contact that comprises a contact length of greater than 40 Angstroms.

3. The semiconductor device of claim 1, wherein the contact exhibits a Schottky Barrier Height of less than 0.5 eV.

4. The semiconductor device of claim 1, wherein the contact length is less than or about 30 Angstroms.

5. The semiconductor device of claim 1, wherein the contact length is less than or about 20 Angstroms.

6. The semiconductor device of claim 1, wherein the silicide comprises at least a first metal, the at least a first metal comprising titanium, zirconium, nickel, molybdenum, or a combination thereof.

7. The semiconductor device of claim 1, wherein the silicide comprises a mono-silicide, a di-silicide, or a combination thereof.

8. The semiconductor device of claim 1, wherein an interface between the substrate and the contact comprises an interface area having greater than or about 40% of metal atoms based on the total number of atoms in the interface area.

9. The semiconductor device of claim 1, wherein the contact is disposed in a n-MOS region.

10. The semiconductor device of claim 1, wherein silicon oxide layer is disposed in a p-MOS region.

11. A semiconductor device, comprising:
a silicon-containing substrate,
an oxide disposed on the substrate defining one or more features; and
a contact comprising a silicide overlying at least a portion of the silicon-containing substrate in the one or more features;
wherein the contact comprises a contact length of less than 40 Angstroms.

12. The semiconductor device processing system of claim 11, wherein the silicide comprises at least a first metal, the at least a first metal comprising molybdenum, titanium, zirconium, nickel, or a combination thereof.

13. The semiconductor device of claim 11, wherein the contact exhibits a Schottky Barrier Height of less than 0.5 eV.

14. A method of forming a semiconductor device, comprising:
depositing at least a first metal layer containing a first metal over a silicon containing substrate; and
annealing the semiconductor device, forming a metal silicide contact between the silicon containing substrate and the at least a first metal layer;
wherein the contact comprises a contact length of less than 40 Angstroms.

15. The method of claim 14, wherein the metal silicide contact is a mono-silicide or a di-silicide.

16. The method of claim 15, wherein depositing the first metal layer includes exposing silicon oxide layer to a first metal precursor and a first metal reactant.

17. The method of claim 14, wherein the contact exhibits a Schottky Barrier Height of less than 0.5 eV.

18. The method of claim 14, wherein the at least a first metal layer is deposited in a p-MOS region or a n-MOS region of a semiconductor device.

19. The method of claim 14, wherein the contact length is less than or about 20 Angstroms.

20. The method of claim 14, further comprising a second annealing operation subsequent the annealing.
